(19) United States
(12) Patent Application Publication
(10) Pub. No.: US 2010/0233836 A1
(43) Pub. Date: Sep. 16, 2010

(54) METHOD FOR MANUFACTURING ZINC OXIDE BASED SEMICONDUCTOR DEVICE

(75) Inventors: Chizu KYOTANI, Tokyo (JP); Michihiro Sano, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Stanley Electric Co., Ltd., Tokyo (JP)

(21) Appl. No.: 12/721,869

(22) Filed: Mar. 11, 2010

(30) Foreign Application Priority Data
Mar. 11, 2009 (JP) 2009-058183

(51) Int. Cl. H01L 33/28; H01L 21/36; H01L 21/443

(52) U.S. Cl. 438/46; 438/104; 438/575; 257/E21.461; 257/E21.478; 257/E33.022

(57) ABSTRACT

A method for manufacturing a ZnO based compound semiconductor device including a contact for a p-type ZnO based compound semiconductor electrode is provided. The method includes forming a stacked body including a substrate, and an n-type ZnO based semiconductor layer and a p-type ZnO based semiconductor layer on the substrate, with the p-type ZnO based semiconductor layer exposed to outside. The stacked body is subjected to heat treatment so that a surface temperature of the p-type ZnO based semiconductor layer is in the range of 250° C. to 500° C. After the heat treatment, a p-side metal electrode is formed on the p-type ZnO based semiconductor layer at a temperature lower than 550° C. And an n-side metal electrode is formed on the n-type ZnO based semiconductor layer.

### CROSS-REFERENCE TO RELATED APPLICATION

This application claims the priority benefit under 35 U.S.C. §119 of Japanese Patent Application No. 2009-058183 filed on Mar. 11, 2009, which is hereby incorporated in its entirety by reference.

### BACKGROUND OF THE INVENTION

1. Field of the Invention

The present invention relates to a method for manufacturing a zinc oxide based semiconductor device, and in particular, to a method for manufacturing a zinc oxide based compound semiconductor device including a contact electrode that has a high adhesion property and provides favorable low resistance ohmic contact.

2. Description of the Related Art

Zinc oxide (ZnO) is a direct bandgap semiconductor having a bandgap energy of 3.37 eV. Such a zinc oxide semiconductor is expected to be used as a material for light emitting devices that emit light in a blue to ultraviolet region. In particular, a zinc oxide semiconductor has specific properties suitable for a semiconductor light emitting device, including an exciton bound energy of 60 meV and a refractive index n of 2.0. It is possible to apply a zinc oxide semiconductor not only to a light emitting device and a light receiving device, but also to a surface acoustic wave (SAW) device, a piezoelectric device, and other electronic devices. A zinc oxide semiconductor is also advantageous in that its raw material is available at relatively low cost and in that zinc oxide does not cause environmental damage and is harmless to humans.

It is generally known that an oxide crystal has a poor adhesion property to metals. It is therefore easy to peel off a metal oxide from a metal. Semiconductors that do not include oxide (such as AlGaAs, InAlGaP, InGaN, and the like) do not have such problems with regard to tight contact and adhesion properties to electrode metals. Because ZnO based semiconductor is a metal oxide, however, it has a poor adhesion property to metal materials, such as gold (Au), silver (Ag), rhodium (Rh), platinum (Pt), and palladium (Pd), in particular. Accordingly, in the process of manufacturing a p-type electrode, a problem is encountered in that a metal electrode formed on a ZnO film can be peeled off from the ZnO film (see, for example, Japanese Patent Application Laid-Open Nos. 2003-110142 and 2004-207440).

On the other hand, ZnO based compounds are wide bandgap semiconductors, and accordingly, metal materials having a favorable ohmic property to be used as a p-type electrode for the ZnO based compounds are limited to certain materials. It is therefore important to form a metal contact electrode that provides favorable low resistance ohmic contact and has a high adhesion property in order to achieve a ZnO based semiconductor device.

However, the formation of contact electrodes that can provide favorable low resistance ohmic contact and have a high adhesion property has not been intensively examined in association with ZnO based compound semiconductor crystals. The present invention was completed based on examinations of a variety of metal materials used for a metal electrode of a p-type ZnO based compound semiconductor.

Specifically, Au was subjected to alloying treatment to be used as a p-side electrode metal (transparent electrode) for a p-type ZnO based compound semiconductor. After the alloying treatment, the resulting Au electrode was visually observed by a stereomicroscope, and it was revealed that the metal electrode was discolored. Furthermore, the discolored portion of the metal electrode was observed by transmission electron microscopy (TEM). FIG. 1 shows the TEM cross-sectional view of the discolored portion of the electrode. As shown in the TEM image, the discolored portion of the Au electrode was confirmed to be peeled off.

In another experiment, Ni/Au was subjected to alloying treatment to be used as a p-side transmission electrode. After the alloying treatment, the resulting Ni/Au electrode was visually observed by a stereomicroscope, and it was revealed that the metal electrode was discolored. FIG. 2 shows the TEM cross-sectional view of the discolored portion of the electrode. As shown in the TEM image, a portion of the Ni/Au electrode was confirmed to be peeled off and aggregated.

In still another experiment, Ti/Au was subjected to alloying treatment to be used as a p-side transmission electrode. After the alloying treatment, the resulting Ti/Au electrode was visually observed by a stereomicroscope, and it was revealed that the metal electrode was not discolored. Furthermore, the Ti/Au electrode was observed by TEM, and the electrode did not have a peeled-off portion. The electric properties were examined for I-V characteristics using a curve tracer. The device did not show a Schottky characteristic, meaning that favorable diode properties were not obtained.

Thus, when a p-side electrode metal is deposited on a p-type ZnO based compound semiconductor and simply alloyed, the resulting electrodes may be peeled off or aggregated and favorable ohmic contact cannot be obtained.

### SUMMARY OF THE INVENTION

One object of the present invention is to provide a method for forming a contact electrode for a p-type ZnO based compound semiconductor that has a high adhesive property and provides a favorable low resistance ohmic contact, without the creation of a peeled-off portion and aggregation of the electrode, as well as a method for manufacturing a ZnO based compound semiconductor device comprising such an electrode.

According to one aspect of the present invention, a method for manufacturing a zinc oxide (ZnO) based semiconductor device may include: forming a stacked body including a substrate, and an n-type ZnO based semiconductor layer and a p-type ZnO based semiconductor layer on the substrate, with the p-type ZnO based semiconductor layer exposed to outside; subjecting the stacked body to heat treatment so that a surface temperature of the p-type ZnO based semiconductor layer is in a range of 250° C. to 500° C.; after the heat treatment, forming a p-side metal electrode on the p-type ZnO based semiconductor layer at a temperature lower than 550° C.; and forming an n-side metal electrode on a side of the n-type ZnO based semiconductor layer.

The heat treatment can be performed in an atmosphere containing at least one gas selected from the group consisting of O₂, H₂O, N₂O, and O₃, wherein each selected gas is contained in an amount of 20 vol % or more.

The p-side metal electrode may comprise a metal selected from the group consisting of Au, Ag, Ni, Rh, Pt, and Pd, alloys of the metal, and stacked metal materials of the metal.

### BRIEF DESCRIPTION OF DRAWINGS

These and other characteristics, features, and advantages of the present invention will become clear from the following description with reference to the accompanying drawings, wherein:

FIG. 1 is a TEM cross-sectional view of a discolored portion of a p-side electrode made of Au after alloying treatment;

FIG. 2 is a TEM cross-sectional view of a discolored portion of a p-side electrode made of Au after alloying treatment;

FIG. 3 is a flow chart showing a method for manufacturing a semiconductor device of the present invention;

FIG. 4 is a cross sectional view illustrating a substrate with an LED operation layer in which a ZnO based semiconductor layer has been grown on a ZnO substrate;

FIG. 5 is a cross sectional view illustrating a substrate with an operation layer in which a p-side electrode and an n-side electrode have been formed;

FIG. 6 is a cross sectional view of an LED device formed by scribing and breaking a wafer (a substrate with an operation layer) in which a p-side electrode and an n-side electrode have been formed, to separate individual chips;

FIG. 7 is a TEM cross-sectional view of a portion of a p-side electrode of an LED device in which a p-ZnO layer was annealed under a temperature condition of 400° C. for 20 min., then Ni/Au was deposited, alloyed, and subjected to transparency treatment;

FIG. 8 is a graph showing the current-voltage characteristics (I-V characteristics) of the LED device shown in FIG. 7;

FIG. 9 is a graph showing the I-V characteristics of an LED device in which the p-ZnO layer was subjected to annealing treatment at 500° C. for 5 min;

FIG. 10 is a cross sectional view illustrating a structure of an LED device in which an MgₓZn₍₁₋ₓ₎O semiconductor layer has been grown on a ZnO substrate; and

FIG. 11 is a graph showing the I-V characteristics of the LED device shown in FIG. 10.

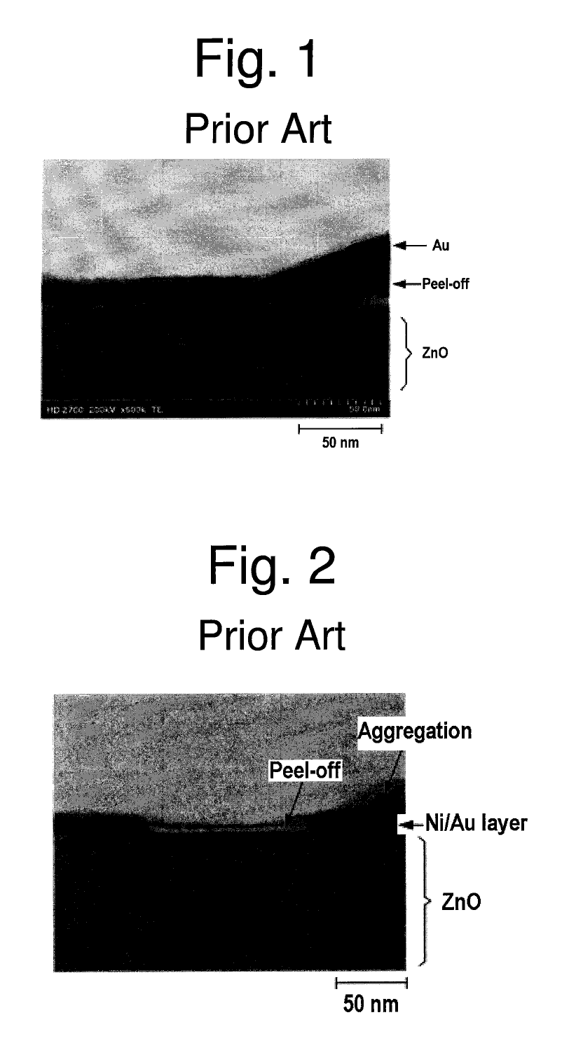

### DETAILED DESCRIPTION

Exemplary embodiments of a method for forming a metal electrode on a ZnO based crystalline stacked body and a method for manufacturing a ZnO based semiconductor device including the metal electrode of the present invention will be describe below with reference to the accompanying drawings. The electrode formation method can include stacking a crystalline layer of a ZnO based compound semiconductor on a zinc oxide (ZnO) substrate and forming a metal electrode on the crystalline stacked body. In addition, examples will be described in which a semiconductor light emitting operation layer utilized in the manufacture of a semiconductor light emitting element (for example, light emitting diode (LED)) is grown as the semiconductor crystalline stacked body.

### Example 1

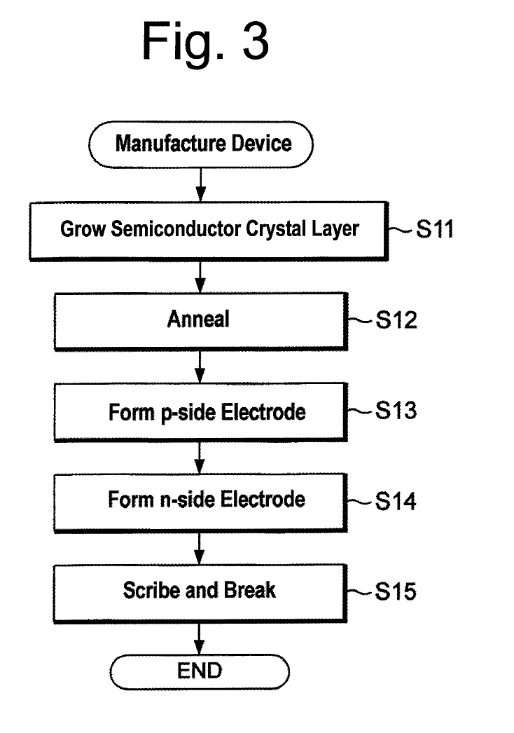

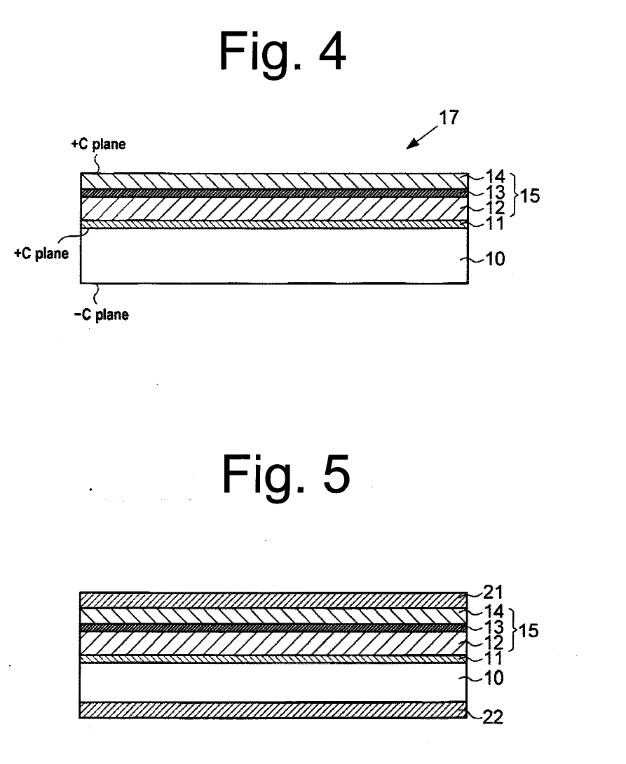

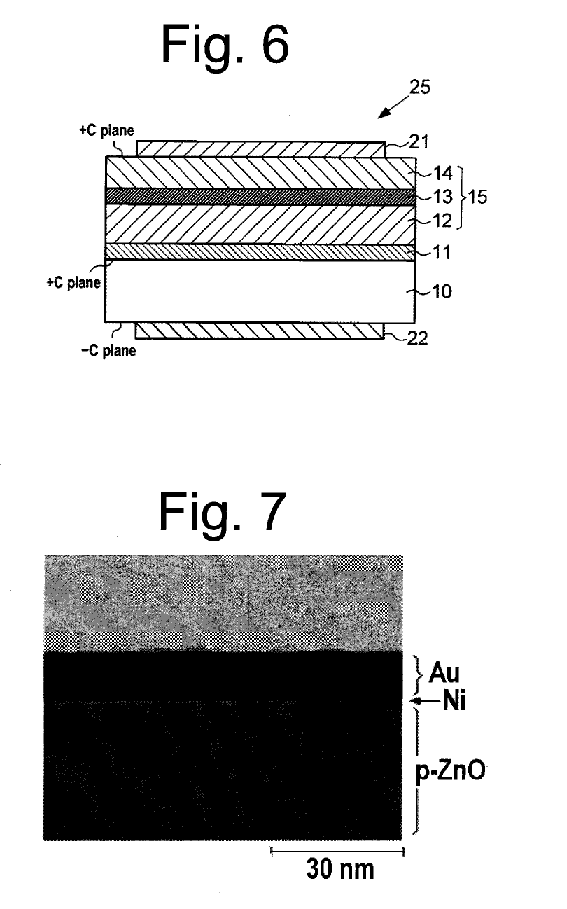

With reference to the flow chart as shown in FIG. 3, a method for manufacturing a ZnO based semiconductor light emitting device according to the present invention will be described. FIG. 4 is a cross sectional view illustrating a substrate with an LED operation layer in which a ZnO based compound semiconductor layer (sometimes simply referred to herein as a “ZnO based semiconductor layer”) has been grown on a ZnO substrate. The substrate is in the shape of a wafer, although the wafer shape is not explicitly described in the following procedures and accompanying drawings.

First, the ZnO based semiconductor layer (semiconductor crystal layer) is grown (step S11 in FIG. 3). ZnO based compound semiconductor layers are sequentially deposited on a substrate 10. The substrate 10 is made of a ZnO single crystal having a wurtzite structure with a principle plane of {0001}, and has a thickness of 500 μm. Specifically, the ZnO based semiconductor layers are sequentially grown with a Zn polar plane (+C plane) as a crystalline growth plane. As shown in FIG. 4, for example, a buffer layer 11, an n-type ZnO (n-ZnO) layer 12, a light emitting layer 13, and a p-type ZnO (p-ZnO) layer 14 are grown on a +C plane of the ZnO substrate 10 using a radical source molecular beam epitaxy (RS-MBE) apparatus in this order. In this manner, the operation layer (LED operation layer) 15 composed of the n-ZnO layer 12, the light emitting layer 13, and the p-ZnO layer 14 can be formed, thereby configuring a substrate 17 having an LED operation layer. It should be noted that the crystalline growth method is not limited to the RS-MBE method, but may be a MOCVD (Metal Organic Chemical Vapor Deposition) method or the like.

Herein, the operation layer or element operation layer may be a layer composed of semiconductors that are combined to impart the required functions of a semiconductor device. For example, a simple transistor may include a structural layer composed of an n-type semiconductor, a p-type semiconductor and an n-type semiconductor with pn junctions (alternatively, a combination of a p-type semiconductor, an n-type semiconductor, and a p-type semiconductor).

It should be noted that a semiconductor structural layer that is constituted by a p-type semiconductor layer, a light emitting layer, and an n-type semiconductor layer (or a p-type semiconductor layer and an n-type semiconductor layer) and achieves a light emitting operation by recombining injected carriers may be employed as a light emitting operation layer. In particular, when the resulting semiconductor device is an LED, it may be referred to as an LED operation layer.

The thicknesses, dopant concentrations, and the like of the buffer layer 11, the n-ZnO layer 12, the light emitting layer 13, and the p-ZnO layer 14 may be designed in a general manner. For example, the buffer layer 11 may be formed by a low temperature growth method so as to have a thickness of several nm to several μm and be doped with an impurity (for example, Ga) to be formed into an n-type ZnO layer. The n-ZnO layer 12 may have a thickness of several tens of nm to several μm and be doped with an impurity (for example, Ga) in a concentration range of approximately 1×10¹⁷ to 5×10¹⁸ cm⁻³ to be formed into an n-type ZnO layer. The light emitting layer 13 may be designed to comprise a multi-quantum well (MQW) layer including a quantum well layer and a barrier layer each having a thickness of several nm, or an MgₓZn₍₁₋ₓ₎O (0≦X≦0.5) having a single composition. And the p-ZnO layer 14 may have a thickness of several tens of nm to several μm and be doped with nitrogen (N) in a concentration of approximately 1×10²⁰ cm⁻³ to be formed into a p-type ZnO layer.

The present invention is not limited to this configuration, and can be designed to have an appropriate structure in order to provide required device characteristics (LED characteristics).

Next, the substrate 17 having an LED operation layer (hereinafter, sometimes simply referred to as the “substrate having the operation layer”) is used for the formation of metal electrode. First, the substrate 17 having the LED operation layer is subjected to heat treatment (annealing) (step S12 in FIG. 3). Specifically, the substrate 17 is subjected to annealing for several minutes to several hours using a rapid thermal annealer (RTA) or other apparatus under a temperature condition such that the surface temperature is controlled to be 500° C. or lower, in an atmosphere of a single gas or a mixed gas containing at least one gas selected from the group consisting of O₂, H₂O, N₂O and O₃ with each selected gas contained in an amount of 20 vol % or more up to 100 vol %. The mixed gas used herein may be a mixed gas containing O₂, H₂O, N₂O, O₃, or the like, and a rare gas including Ar or the like or N₂.

Next as shown in FIG. 5, an Ni/Au layer can be deposited on the surface of the p-ZnO layer 14 by an electron beam deposition technique to serve as a p-side electrode 21. The Ni and Au layers of the Ni/Au layer can have thicknesses of 1 nm and 10 nm, respectively. After the deposition, the Ni/Au layer can be patterned by a photolithography technique to form a p-side electrode with a predetermined pattern. Then, the Ni/Au layer is alloyed and subjected to transparency treatment using an RTA or other apparatus under a temperature condition such that the surface temperature is controlled to be 500° C. or lower, in an atmosphere of a single gas or a mixed gas containing at least one gas selected from the group consisting of O₂, H₂O, N₂O and O₃ with each selected gas contained in an amount of 20 vol % or more up to 100 vol % (step S13). In this step, the mixed gas can contain a rare gas. This can complete the formation of the p-side electrode 21.

Next, the surface of the substrate 17 having the operation layer is attached to a grinder so that the rear surface of the substrate 17 opposite from the p-side electrode 21 (the −C plane side of the ZnO substrate 10) is polished to have a mirror surface (optical mirror surface). After polishing, the thickness of the substrate 17 having the operation layer may be, for example, approximately 200 μm. Then, a resist mask can be formed on the rear surface of the substrate by a photolithography technique to have a pattern of an n-side electrode 22. After that, Ti/Au is deposited by an electron beam (EB) deposition such that the Ti layer and the Au layer of the Ti/Au layer have thicknesses of 10 nm and 100 nm, respectively, to serve as an n-side electrode 22. The resulting Ti/Au layer can be partly removed in parts not corresponding to the openings of the resist mask by a lift-off technique, and then can be alloyed at temperatures of 500° C. or lower to complete the n-side electrode 22 (step S14).

The wafer (the substrate having the operation layer) in which the p-side electrode 21 and the n-side electrode 22 have been formed can be separated by scribing and breaking into individual chips (step S15). This completes the LED device 25.

It is important that all of the steps of the device formation process be carried out at temperatures lower than 550° C. In particular, it is preferred that all of the steps be carried out at temperatures of 500° C. or lower. The reason why the temperatures should be controlled will be described below.

[Formation Conditions and Characteristics of p-Side Electrode]

As described above, before the metal for the p-side electrode is deposited, the p-ZnO layer 14 of the substrate 17 having the LED operation layer should be annealed. The inventors have examined the variation of the p-ZnO layer 14 caused by annealing.

First, a buffer layer was grown on a ZnO substrate having a +C plane as a principle plane, and a ZnO layer was grown while doped with nitrogen (N) as a p-type dopant in a concentration of 1×10²⁰ cm⁻³ so as to form a p-doped ZnO layer. This provided an epitaxy substrate for the examination. Then, while the epitaxy substrate was heated so that the surface temperature thereof reached 500 to 800° C., an annealing treatment was carried out in an oxygen (O₂) atmosphere for 1 second. After the annealing, the capacitance-voltage characteristics (C-V characteristics) of the p-doped ZnO layer were measured, and the carrier concentration variation due to the annealing at various temperatures was calculated. The results are shown in Table 1.

TABLE 1

| Temperature (° C.) | 500 | 550 | 600 | 650 | 700 | 750 | 800 |
|---|---|---|---|---|---|---|---|
| Carrier Conc. | 3.03 × 10¹⁷ | 4.00 × 10¹⁷ | 6.16 × 10¹⁷ | 9.39 × 10¹⁷ | 1.37 × 10¹⁸ | 3.79 × 10¹⁸ | 6.44 × 10¹⁸ |
| Conductivity | p-type | n-type | n-type | n-type | n-type | n-type | n-type |

As shown in Table 1, when the anneal temperature (or the surface temperature of the p-doped ZnO layer) was 500° C. (or lower), the p-doped ZnO layer showed the p-type conductivity. When the temperature was 550° C. or higher, the conductivity was changed into the n-type. When the annealing was carried out at the higher temperature, the donor concentration (cm⁻³) was increased. It is thought that oxygen may be drawn from the ZnO crystal at such higher temperatures, thereby forming a number of oxygen holes, so that the donor concentration can increase. Accordingly, when the annealing is carried out at such a high temperature range, the donor concentration can increase to impart the n-type conductivity to the semiconductor. In order to maintain the p-type conductivity of the p-doped ZnO layer, it is required that the annealing temperatures before the deposition of the p-side electrode metal should be lower than 550° C. It is more preferable that the annealing be carried out at an annealing temperature of 500° C. or lower in order to ensure the p-type conductivity.

It should be noted that the surface temperature when annealing is calibrated as follows: A sample having Al deposited on the surface thereof is disposed on the holder for holding the substrate 17, and the emissivity is adjusted so that the melting point (660.4° C.) thereof is matched to the temperature detected by an infrared thermometer when the deposited Al is actually melted.

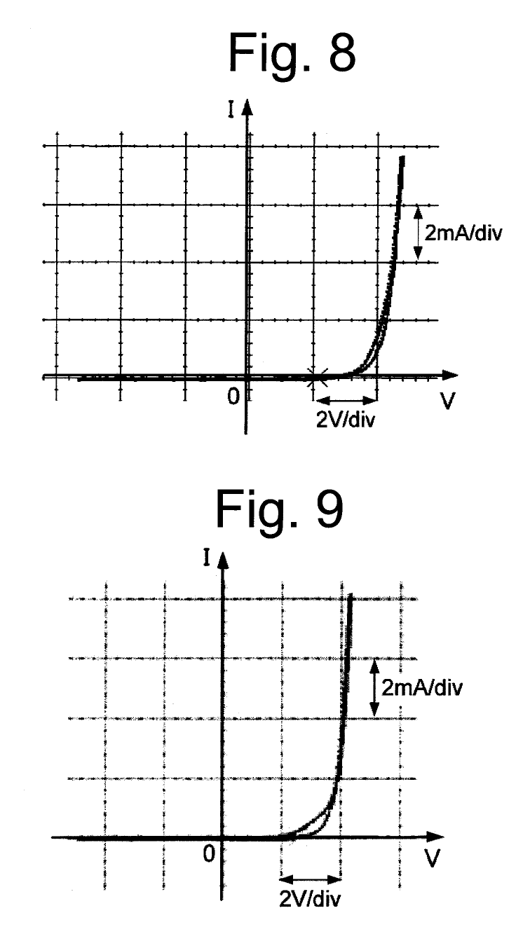

FIG. 7 is a TEM cross-sectional view of a portion of a p-side electrode of an LED device formed according to the method shown in FIG. 3 and described above. FIG. 8 is a graph showing the current-voltage characteristics (I-V characteristics) of the LED device shown in FIG. 7. A p-side metal electrode 21 was formed using the substrate 17 having an LED operation layer grown in the manner described above (step S11).

Specifically, the substrate 17 having the grown operation layer was subjected to annealing using an RTA in a 100% O₂ gas atmosphere at a surface temperature of 400° C. for 20 minutes (step S12).

Next, Ni/Au was deposited on the surface of the p-ZnO layer 14 by an electron beam deposition technique, and the Ni/Au layer was patterned by a photolithography technique. The Ni/Au layer was alloyed and subjected to transparency treatment using an RTA at a surface temperature of 450° C. in a 100% O₂ gas atmosphere for 30 seconds (step S13) to form the p-side electrode 21.

Then the n-side electrode 22 was formed in the same manner as that described above to complete the LED device 25 (steps S14 and S15).

The p-side electrode 21 of the LED device 25 was visually observed by a stereomicroscope, and it was revealed that the p-side electrode 21 was not discolored. FIG. 7 is a TEM cross-sectional view of a portion of the p-side electrode 21 and the substrate 17 near the electrode 21. According to the TEM observation, no peeled-off portion and no metal aggregation were generated in the p-side electrode 21, and it was confirmed that the p-side electrode 21 was in close contact with the surface of the p-ZnO layer 14.

The diode characteristics of the LED device 25 were evaluated. FIG. 8 is a graph showing the current-voltage characteristics (I-V characteristics) of the LED device 25 measured by a curve tracer. According to the results, it was confirmed that a favorable ohmic contact was formed and that favorable diode characteristics in both the forward direction and the reverse direction could be ensured.

Next, the anneal condition was altered to evaluate the same points. Specifically, the annealing temperature was set to 500° C. and the annealing period was set to 5 minutes. The atmosphere for annealing was the same as before (100% O₂ gas atmosphere). The p-side electrode 21 of the LED device 25 formed with these conditions was visually observed by a stereomicroscope. It was confirmed that the p-side electrode 21 was not discolored and that no peeled-off portion and no metal aggregation were generated in the p-side electrode 21. FIG. 9 is a graph showing the I-V characteristics of the LED device 25. According to the results, it was confirmed that a favorable ohmic contact was formed and that favorable diode characteristics in both the forward direction and the reverse direction could be ensured.

Thus, even when the annealing temperature rises to a certain level and the annealing period is shortened, the same effect can be attained. Furthermore, the inventors have confirmed that when the annealing temperature was 500° C. and the annealing period was 2 hours, the same effect could be attained. That is, it has been revealed that when the above conditions were adopted, no peeled-off portions and no metal aggregation were generated in the electrode, while the p-type conductivity was maintained. Although the effect is not harmed by the extended annealing period, in view of productivity it is desirable to perform the annealing treatment at high temperatures (for example, 500° C.) for short time periods (for example, 5 minutes).

It is thought that the effect of annealing before the deposition of metal for the p-side electrode is related to the surface activation of the ZnO crystal. Namely, it is considered that the surface of the ZnO crystal can be activated more when a higher temperature is used for annealing. It is said that an alteration of unpaired electrons in ZnO occurs when the surface temperature of ZnO crystal is 250° C. or higher according to several test results of ESR (Electron Spin Resonance). The lower limit for the annealing temperature would therefore be around 250° C., in view of the assumption that the results of the present invention whereby no peeled-off electrode and metal aggregation are generated in the electrode are caused by the activation of the surface of ZnO crystal by the annealing before the deposition of the p-side electrode metal. In addition, as described above, it is required that the annealing temperature be lower than 550° C. in order to maintain the p-type conductivity of the p-doped ZnO layer. Accordingly, the temperature during the entire process including the electrode formation and the semiconductor element formation processes should be lower than 550° C. The temperature is preferably 500° C. or lower to maintain the p-type conductivity as explained above.

### Example 2

In Example 1, the buffer layer 11, the n-ZnO layer 12, the light emitting layer 13, and the p-ZnO layer 14 are grown on the +C plane of the ZnO substrate 10 to form the substrate 17 having the operation layer. In the present example, instead of ZnO crystal, ZnO based semiconductor crystals including magnesium (Mg) or the like are used. Specifically, in the present example, the n-ZnO layer and the p-ZnO layer are made of a ZnO based semiconductor layer such as MgₓZn₍₁₋ₓ₎O (0≦X≦0.5). In this case, as in the previous Example 1, the p-type conductivity can be maintained while the p-side electrode can be formed without peeled-off portions and metal aggregation.

It should be noted that X is limited to 0.5 or less in MgₓZn₍₁₋ₓ₎O because if X exceeds 0.5 the crystals of MgZnO based semiconductor may include both hexagonal and cubic crystals, resulting in deterioration of the crystallinity.

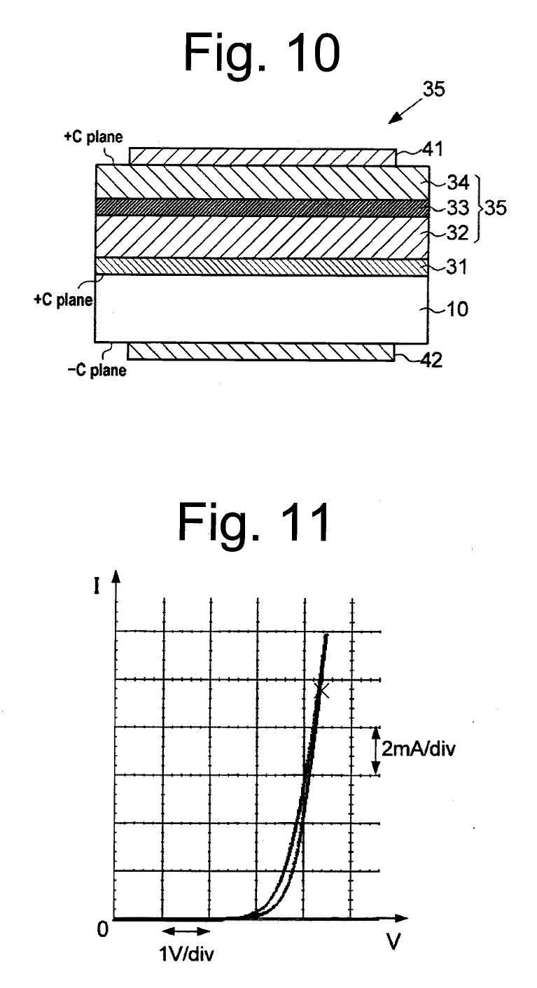

FIG. 10 is a cross sectional view illustrating a structure of a light emitting device 35 (LED device) in which an MgₓZn₍₁₋ₓ₎O based semiconductor layer has been grown on a ZnO substrate 10. Specifically, a buffer layer 31, an n-Mg_{0.31}Zn_{0.69}O layer 32, a ZnO light emitting layer 33, and a p-Mg_{0.33}Zn_{0.67}O layer 34 were grown on the +C plane of the ZnO substrate 10. In this manner, an operation layer 35 (LED operation layer) constituted by the n-MgₓZn₍₁₋ₓ₎O layer 32, the ZnO light emitting layer 33, and the p-MgₓZn₍₁₋ₓ₎O layer 34 was formed. The p-MgₓZn₍₁₋ₓ₎O layer 34 was formed by doping with nitrogen (N being a p-type dopant) in a concentration of 1×10²⁰ cm⁻³. The n-MgₓZn₍₁₋ₓ₎O layer 32 was formed by doping with an n-type dopant (for example, Ga) in a concentration range of approximately 1×10¹⁷ to 5×10¹⁸ cm⁻³ as in Example 1.

The processes and the conditions for the semiconductor crystals growing process, the annealing process before the deposition of the p-side electrode metal, the formation processes of the p-side electrode and the n-side electrode are the same as in Example 1. Specifically, for example, the annealing was carried out at a temperature of 400° C. for 20 minutes before the metal for the p-side electrode was deposited. Ni/Au was deposited on the surface of the p-MgₓZn₍₁₋ₓ₎O layer 34. The Ni and Au layers of the Ni/Au layer had thicknesses of 1 nm and 10 nm, respectively, as in Example 1. Then, the Ni/Au layer was patterned using a photolithography technique. The Ni/Au layer was alloyed and subjected to transparency treatment using an RTA at a surface temperature of 450° C. in a 100% O₂ gas atmosphere for 30 seconds to form the p-side electrode 41. Then, the rear surface of the ZnO substrate 10 (or −C plane) was polished to become a mirror surface, and Ti/Au was deposited by electron beam deposition such that the Ti layer and the Au layer of the Ti/Au layer had thicknesses of 10 nm and 100 nm, respectively. After being patterned, the Ti/Au layer was alloyed at temperatures of 500° C. or lower to form an n-side electrode 42. Accordingly, the LED device 35 was completed through processes that were all conducted at temperatures at or lower than 500° C.

The p-side electrode 41 of the LED device 35 formed in this manner was visually observed by a stereomicroscope, and it was revealed that the p-side electrode 41 was not discolored. Accordingly, as described above, no peeled-off portion and no metal aggregation were generated in the p-side electrode 41 of the LED device 35, and it was confirmed that the p-side electrode 41 was in close contact with the surface of the p-MgₓZn₍₁₋ₓ₎O layer 34.

Accordingly, even when the ZnO based semiconductor including Mg as a component (MgₓZn₍₁₋ₓ₎O) is used, the surface of the p-ZnO based semiconductor layer can be activated by annealing before the electrode formation. This can prevent metal aggregation and peeling-off of the electrode, thereby resulting in the electrode having a favorable adhesive property.

FIG. 11 is a graph showing the I-V characteristics of the LED device 35 formed as described above. According to the results, it was confirmed that a favorable ohmic contact was formed and that favorable diode characteristics in both the forward direction and the reverse direction could be ensured.

As described above, the advantageous effects of the annealing according to the present invention can be obtained in all types of ZnO based semiconductor devices because the effects are assumed to be caused by the activation of the surface of the ZnO based crystal.

In the above specific examples, the p-side electrodes were formed by Ni/Au. However, the p-side electrode can be made of a metal selected from the group consisting of Au, Ag, Ni, Rh, Pt, Pd, alloys of them and stacked metal materials of them. Examples of the p-side electrode metal include Ni/Pt/Au, Ni/Rh/Au, and the like. The first layer of them may be Al, Sn, Pb or the like, instead of Ni. In the above specific examples, the annealing was performed in a 100% O₂ gas atmosphere. The annealing may be performed in an atmosphere of a single gas or a mixed gas containing at least one gas selected from the group consisting of O₂, H₂O, N₂O and O₃ with each selected gas contained in an amount of 20 vol % or more up to 100 vol %. The mixed gas used herein may be a mixed gas containing O₂, H₂O, N₂O, O₃, or the like, and a rare gas including Ar or the like or N₂.

In the above specific examples, the LED was illustrated as an example of the semiconductor light emitting device. Of course, the present invention can be applied to a semiconductor laser or other electronic devices.

As described above, the present invention can provide a method for forming a contact electrode for a p-type ZnO based compound semiconductor that has a high adhesive property and provides a favorable low resistance ohmic contact without the creation of a peeled-off portion and aggregation of the electrode, as well as a method for manufacturing a ZnO based compound semiconductor device comprising such an electrode.

It will be apparent to those skilled in the art that various modifications and variations can be made in the present invention without departing from the spirit or scope of the present invention. Thus, it is intended that the present invention cover the modifications and variations of the present invention provided they come within the scope of the appended claims and their equivalents. All related art references described above are hereby incorporated in their entirety by reference.

What is claimed is:

1. A method for manufacturing a zinc oxide (ZnO) based semiconductor device, comprising:
forming a stacked body including a substrate, and an n-type ZnO based semiconductor layer and a p-type ZnO based semiconductor layer on the substrate, with the p-type ZnO based semiconductor layer exposed to outside;
subjecting the stacked body to heat treatment so that a surface temperature of the p-type ZnO based semiconductor layer is in a range of 250° C. to 500° C.;
after the heat treatment, forming a p-side metal electrode on the p-type ZnO based semiconductor layer at a temperature lower than 550° C.; and
forming an n-side metal electrode on a side of the n-type ZnO based semiconductor layer.

2. The manufacturing method according to claim 1, wherein the heat treatment is performed in an atmosphere containing at least one gas selected from the group consisting of O₂, H₂O, N₂O and O₃, wherein each selected gas is contained in an amount of 20 vol % or more.

3. The manufacturing method according to claim 1, wherein the p-side metal electrode comprises a metal selected from the group consisting of Au, Ag, Ni, Rh, Pt, and Pd, alloys of said metal, and stacked metal materials of said metal.

4. The manufacturing method according to claim 2, wherein the p-side metal electrode comprises a metal selected from the group consisting of Au, Ag, Ni, Rh, Pt, and Pd, alloys of said metal, and stacked metal materials of said metal.

5. The manufacturing method according to claim 1, wherein each of the p-type ZnO based semiconductor layer and the n-type ZnO based semiconductor layer is an MgₓZn₍₁₋ₓ₎O (0≦X≦0.5) layer.

6. The manufacturing method according to claim 2, wherein each of the p-type ZnO based semiconductor layer and the n-type ZnO based semiconductor layer is an MgₓZn₍₁₋ₓ₎O (0≦X≦0.5) layer.

7. The manufacturing method according to claim 3, wherein each of the p-type ZnO based semiconductor layer and the n-type ZnO based semiconductor layer is an MgₓZn₍₁₋ₓ₎O (0≦X≦0.5) layer.

8. The manufacturing method according to claim 4, wherein each of the p-type ZnO based semiconductor layer and the n-type ZnO based semiconductor layer is an MgₓZn₍₁₋ₓ₎O (0≦X≦0.5) layer.

9. The manufacturing method according to claim 1, wherein the stacked body includes a light emitting layer, and the ZnO based semiconductor device comprises an LED.

10. The manufacturing method according to claim 2, wherein the stacked body includes a light emitting layer, and the ZnO based semiconductor device comprises an LED.

11. The manufacturing method according to claim 3, wherein the stacked body includes a light emitting layer, and the ZnO based semiconductor device comprises an LED.

12. The manufacturing method according to claim 4, wherein the stacked body includes a light emitting layer, and the ZnO based semiconductor device comprises an LED.

13. The manufacturing method according to claim 5, wherein the stacked body includes a light emitting layer, and the ZnO based semiconductor device comprises an LED.

14. The manufacturing method according to claim 6, wherein the stacked body includes a light emitting layer, and the ZnO based semiconductor device comprises an LED.

15. The manufacturing method according to claim 7, wherein the stacked body includes a light emitting layer, and the ZnO based semiconductor device comprises an LED.

16. The manufacturing method according to claim 8, wherein the stacked body includes a light emitting layer, and the ZnO based semiconductor device comprises an LED.

17. A method for forming a contact electrode for use with a p-type ZnO based semiconductor, comprising:
subjecting a p-type ZnO based semiconductor to heat treatment so that a surface temperature of the p-type ZnO based semiconductor is in a range of 250° C. to 500° C.;
after the heat treatment of the semiconductor, depositing a metal for an electrode on the p-type ZnO based semiconductor at a temperature lower than 550° C.; and
subjecting the metal for the electrode to heat treatment at a temperature lower than 550° C.

18. The forming method according to claim 17, wherein the heat treatment of the semiconductor is performed in an atmosphere containing at least one gas selected from the group consisting of O₂, H₂O, N₂O and O₃, wherein each selected gas is contained in an amount of 20 vol % or more.

19. The forming method according to claim 17, wherein the metal for the electrode comprises a metal selected from the group consisting of Au, Ag, Ni, Rh, Pt, and Pd, alloys of said metal, and stacked metal materials of said metal.

20. The forming method according to claim 18, wherein the metal for the electrode comprises a metal selected from the group consisting of Au, Ag, Ni, Rh, Pt, and Pd, alloys of said metal, and stacked metal materials of said metal.
